(19) United States
(12) Patent Application Publication
(10) Pub. No.: US 2026/0082625 A1
(43) Pub. Date: Mar. 19, 2026

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kenichi MATSUSHITA, Nonoichi Ishikawa (JP)

(21) Appl. No.: 19/196,339

(22) Filed: May 1, 2025

(30) Foreign Application Priority Data
Sep. 19, 2024 (JP) 2024-162662

(51) Int. Cl. H10D 30/66; H10D 30/01; H10D 62/10; H10D 64/00

(52) U.S. Cl. CPC H10D 30/665; H10D 30/0291; H10D 30/668; H10D 62/107; H10D 64/117

(57) ABSTRACT

A semiconductor device including: a first electrode; a semiconductor portion disposed on the first electrode; a second electrode disposed on a cell region of the semiconductor portion; a third electrode disposed on a termination region of the semiconductor portion; a fourth electrode disposed between the first electrode and the third electrode within the semiconductor portion, and connected to the third electrode; a first insulating film disposed between the semiconductor portion and the fourth electrode.

### CROSS-REFERENCE TO RELATED APPLICATIONS

This application is based upon and claims the benefit of priority from the prior Japanese Patent Application No. 2024-162662, filed on Sep. 19, 2024 the entire contents of which are incorporated herein by reference.

### FIELD

The present invention relates to a semiconductor device and a method for manufacturing semiconductor device.

### BACKGROUND

In vertical power control semiconductor devices, efforts are being made to reduce the thickness of the semiconductor part to lower the on-resistance and switching losses. However, when the semiconductor part is thinned, there is a problem that the semiconductor device is easily destroyed when avalanche breakdown occurs.

### BRIEF DESCRIPTION OF THE DRAWINGS

FIG. 1 is a top view showing the semiconductor device according to the first embodiment.

FIG. 2A is a cross-sectional view along the line A-A′ shown in FIG. 1, and

FIG. 2B is a cross-sectional view along the line B-B′ shown in FIG. 1.

FIG. 3A is a partially enlarged cross-sectional view showing region C in FIG. 2A, and FIG. 3B is a partially enlarged cross-sectional view showing region D in FIG. 2B.

FIG. 4A, FIG. 4B, FIG. 4C, and FIG. 4D are process cross-sectional views showing the method for manufacturing the semiconductor device according to the first embodiment.

FIG. 5 is a cross-sectional view showing the operation of the semiconductor device according to the first embodiment.

FIG. 6 is a cross-sectional view showing the semiconductor device according to the second embodiment.

FIG. 7 is a cross-sectional view showing the semiconductor device according to the third embodiment.

FIG. 8 is a cross-sectional view showing the semiconductor device according to the reference example.

FIG. 9 is a cross-sectional view showing the semiconductor device according to the comparative example.

FIG. 10A, FIG. 10B, FIG. 10C, and FIG. 10D are process cross-sectional views showing the method for manufacturing the semiconductor device according to the comparative example.

FIG. 11 is a graph showing the I-V characteristics of the semiconductor device in the test example, with the voltage applied to the source and drain electrodes of the semiconductor device on the horizontal axis and the current flowing through the source and drain electrodes of the semiconductor device on the vertical axis.

### DETAILED DESCRIPTION

The purpose of the embodiment is to provide a semiconductor device and a method for manufacturing the same that are less likely to be destroyed even when avalanche breakdown occurs.

The semiconductor device according to the embodiment includes a first electrode, a semiconductor part disposed on the first electrode, a second electrode disposed on the cell region of the semiconductor part, a third electrode disposed on the terminal region of the semiconductor part, a fourth electrode disposed between the first electrode and the third electrode within the semiconductor part and connected to the third electrode, and a first insulating film disposed between the semiconductor part and the fourth electrode.

The method for manufacturing the semiconductor device according to the embodiment includes the steps of forming a second semiconductor layer of a second conductivity type in the terminal region of the first semiconductor layer of the first conductivity type by ion implantation of impurities into the first semiconductor layer, forming a third semiconductor layer of the second conductivity type with a carrier concentration higher than that of the second semiconductor layer on the second semiconductor layer within the first semiconductor layer by ion implantation of impurities into the first semiconductor layer, forming a first trench penetrating the third semiconductor layer and reaching the second semiconductor layer, forming a first insulating film on the inner surface of the first trench, forming a fourth electrode in contact with the first insulating film within the first trench, and forming a first electrode connected to the first semiconductor layer, a second electrode disposed on the cell region of the first semiconductor layer, and a third electrode connected to the fourth electrode.

The semiconductor device and the method for manufacturing the same according to the embodiment will be described in detail below with reference to the attached drawings. However, the invention is not limited to these embodiments

### First Embodiment

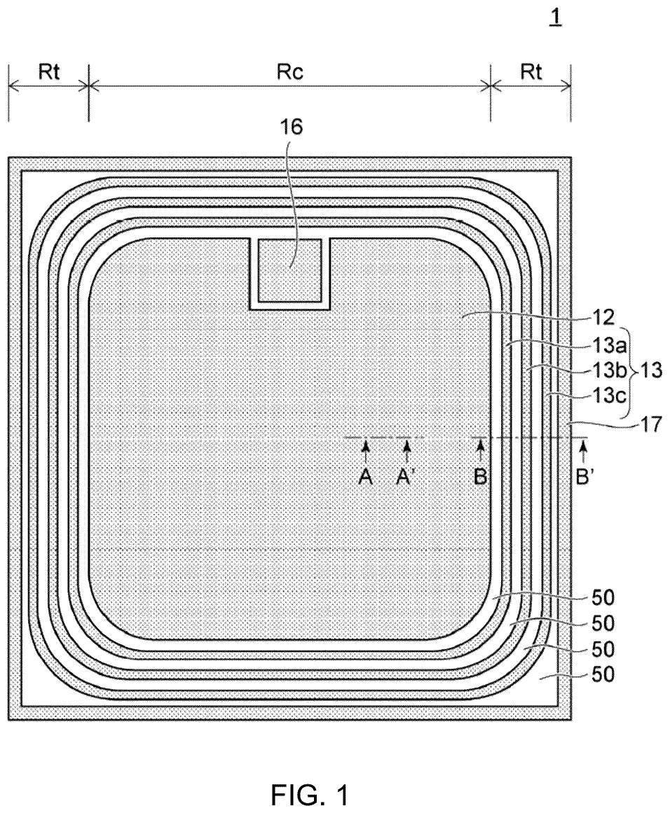

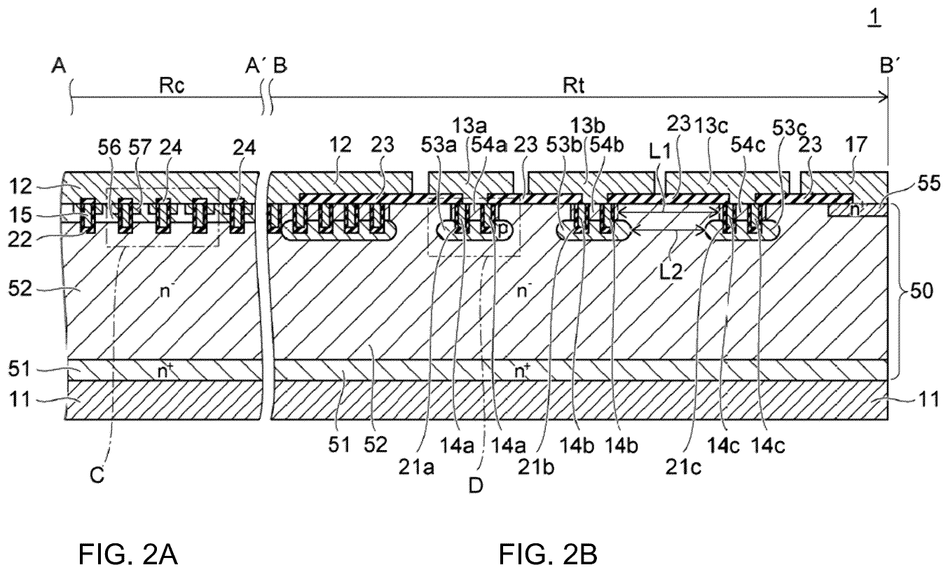

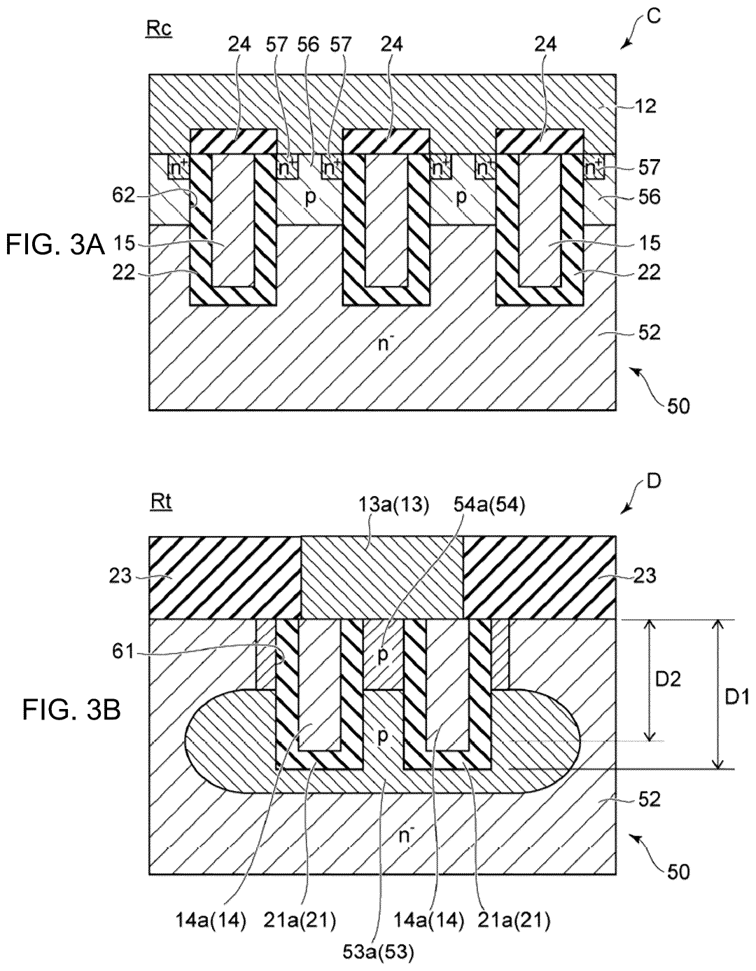

FIG. 1 is a top view showing a semiconductor device according to this embodiment. FIG. 2A is a cross-sectional view taken along line A-A′ shown in FIG. 1, and FIG. 2B is a cross-sectional view taken along line B-B′ shown in FIG. 1. FIG. 3A is a partially enlarged cross-sectional view showing region C in FIG. 2A, and FIG. 3B is a partially enlarged cross-sectional view showing region D in FIG. 2B.

As shown in FIG. 1, FIG. 2A and FIG. 2B, and FIG. 3A and FIG. 3B, the semiconductor device 1 according to this embodiment includes a semiconductor portion 50, a drain electrode 11, a source electrode 12, a field plate electrode (hereinafter referred to as “FP electrode”) 13, a trench electrode 14, a gate electrode 15, a gate pad 16, a termination electrode 17, a trench insulating film 21, a gate insulating film 22, a termination insulating film 23, and a cell insulating film 24.

In this embodiment, an example in which the semiconductor device 1 is a MOSFET (Metal-Oxide-Semiconductor Field-Effect Transistor) is described, but it is not limited to this. As described in the third embodiment, the semiconductor device may be an IGBT (insulated gate bipolar transistor) or another type of semiconductor device.

The semiconductor portion 50 is a chip made of a semiconductor material, such as single-crystal silicon (Si), and the conductivity type is set to n-type or p-type by introducing impurities into each part. The thickness of the semiconductor portion 50 is, for example, between 50 μm and 150 μm. The semiconductor portion 50 has a cell region Rc through which current flows in the vertical direction and a termination region Rt surrounding the cell region Rc.

The drain electrode 11 is disposed on the entire lower surface of the semiconductor portion 50 and is in contact with the semiconductor portion 50. The source electrode 12 and the gate pad 16 are disposed on the upper surface of the cell region Rc of the semiconductor portion 50.

The FP electrode 13 is disposed on the termination region Rt of the semiconductor portion 50. The FP electrode 13 includes, for example, three FP electrodes 13a, 13b, and 13c. Viewed from above, the FP electrode 13a is annular and surrounds the source electrode 12, the FP electrode 13b is annular and surrounds the FP electrode 13a, and the FP electrode 13c is annular and surrounds the FP electrode 13b. The FP electrode 13 is electrically floating. The number of FP electrodes 13 is not particularly limited.

The trench electrode 14 is disposed between the drain electrode 11 and each FP electrode 13 within the semiconductor portion 50. Therefore, the trench electrode 14 is disposed within the termination region Rt. The depth of the trench electrode 14 is, for example, about 5 μm.

The trench electrode 14 includes trench electrodes 14a, 14b, and 14c. The trench electrode 14a is located directly below the FP electrode 13a and is connected to the FP electrode 13a. The trench electrode 14c is located directly below the FP electrode 13c and is connected to the FP electrode 13c. In this specification, “connected” means electrically connected.

Viewed from above, each trench electrode 14 is annular and surrounds the source electrode 12. In this embodiment, two trench electrodes 14 are connected to one FP electrode 13. However, this is not limited to this configuration, and one trench electrode 14 may be connected to one FP electrode 13, or three or more trench electrodes 14 may be connected.

The trench insulating film 21 is disposed between the semiconductor portion 50 and each trench electrode 14. Thus, the trench electrode 14 is insulated from the semiconductor portion 50 by the trench insulating film 21. The trench electrode 14 is connected only to the FP electrode 13. Therefore, the trench electrode 14 is also electrically floating.

The trench insulating film 21 includes trench insulating films 21a, 21b, and 21c. The trench insulating film 21a is disposed between the semiconductor portion 50 and the trench electrode 14a, the trench insulating film 21b is disposed between the semiconductor portion 50 and the trench electrode 14b, and the trench insulating film 21c is disposed between the semiconductor portion 50 and the trench electrode 14c.

The gate electrode 15 is disposed between the drain electrode 11 and the source electrode 12 within the semiconductor portion 50. Therefore, the gate electrode 15 is disposed in the cell region Rc. Multiple gate electrodes 15 are provided, for example, extending in the same direction. The gate electrode 15 is connected to the gate pad 16. Thus, a gate potential is applied to each gate electrode 15 through the gate pad 16.

The gate insulating film 22 is disposed between the semiconductor portion 50 and each gate electrode 15. Thus, each gate electrode 15 is insulated from the semiconductor portion 50 by the gate insulating film 22.

The termination electrode 17 is disposed on the outermost edge of the semiconductor portion 50. Therefore, the termination electrode 17 is disposed in the termination region Rt. The termination electrode 17 is electrically floating.

The termination insulating film 23 is partially disposed between the semiconductor portion 50 and the FP electrode 13, and between the semiconductor portion 50 and the termination electrode 17 in the termination region Rt. Thus, the portions of the semiconductor portion 50 where the FP electrode 13 and the termination electrode 17 are connected are limited.

The cell insulating film 24 is disposed between the gate electrode 15 and the source electrode 12, and between the gate insulating film 22 and the source electrode 12 in the cell region Rc. Thus, the gate electrode 15 is insulated from the source electrode 12 by the cell insulating film 24.

In the semiconductor portion 50, a drain layer 51 of n+ type conductivity, a drift layer 52 of n-type conductivity, a guard ring layer 53 of p type conductivity, a connection layer 54 of p type conductivity, a termination layer 55 of n+ type conductivity, a base layer 56 of p type conductivity, and a source layer 57 of n+ type conductivity are provided. The guard ring layer 53 includes guard ring layers 53a, 53b, and 53c. The connection layer 54 includes connection layers 54a, 54b, and 54c.

The term “n+ type” indicates a higher carrier concentration than “n-type.” The same applies to p-type. “Carrier concentration” refers to the effective impurity concentration contributing to the conductivity of the semiconductor. When both donor and acceptor impurities are present in a region, it refers to the net concentration after offsetting.

The drain layer 51 constitutes the entire lower surface of the semiconductor portion 50, is in contact with the drain electrode 11, and is connected to the drain electrode 11. The drift layer 52 is disposed on the entire surface of the drain layer 51 and is in contact with the drain layer 51. The drain layer 51 and the drift layer 52 constitute the first semiconductor layer.

Viewed from above, the guard ring layer 53b is annular and surrounds the guard ring layer 53a. The connection layer 54b is disposed on the guard ring layer 53b and is in contact with the guard ring layer 53b. Viewed from above, the guard ring layer 53c is annular and surrounds the guard ring layer 53b. The connection layer 54c is disposed on the guard ring layer 53c and is in contact with the guard ring layer 53c. The upper surface of the connection layer 54 constitutes part of the upper surface of the semiconductor portion 50.

The connection layer 54 is in contact with the FP electrode 13 in the region of the upper surface of the semiconductor portion 50 that is not covered by the termination insulating film 23. Therefore, the guard ring layer 53 is connected to the FP electrode 13 via the connection layer 54. The carrier concentration of the connection layer 54 is higher than that of the guard ring layer 53.

The number of guard ring layers 53 and connection layers 54 is the same as the number of FP electrodes 13. In this embodiment, three guard ring layers 53, three connection layers 54, and three FP electrodes 13 are provided, for example. In the horizontal direction, the distance L1 between adjacent connection layers 54 is longer than the distance L2 between adjacent guard ring layers 53. That is, L1>L2.

The termination layer 55 is disposed in the uppermost part of the outermost periphery of the semiconductor portion 50. The termination layer 55 is connected to the drift layer 52 and the termination electrode 17.

In the termination region Rt, the lower part of the trench insulating film 21 is covered by the guard ring layer 53, and the upper part of the trench insulating film 21 is covered by the connection layer 54. As shown in FIG. 3B, in the vertical direction, the distance D1 between the lower end of the trench insulating film 21 and the FP electrode 13 is longer than the distance D2 between the center of the guard ring layer 53 and the FP electrode 13. That is, D1>D2.

The cell region Rc of the semiconductor portion 50 will be described. As shown in FIG. 2A and FIG. 3A, the base layer 56 is disposed on the drift layer 52 in the cell region Rc. As described later, the base layer 56 is formed in the same process as the connection layer 54. Therefore, the carrier concentration distribution of the base layer 56 in the vertical direction is approximately equal to that of the connection layer 54, and the carrier concentration of the base layer 56 is higher than that of the guard ring layer 53.

The source layer 57 is disposed on a part of the base layer 56 and is separated from the drift layer 52 by the base layer 56. The base layer 56 and the source layer 57 constitute part of the upper surface of the semiconductor portion 50 in the cell region Rc and are connected to the source electrode 12 between the cell insulating films 24. In the cell region Rc, the lower part of the gate insulating film 22 is covered by the drift layer 52, the central part in the vertical direction is in contact with the base layer 56, and the upper part is in contact with the source layer 57.

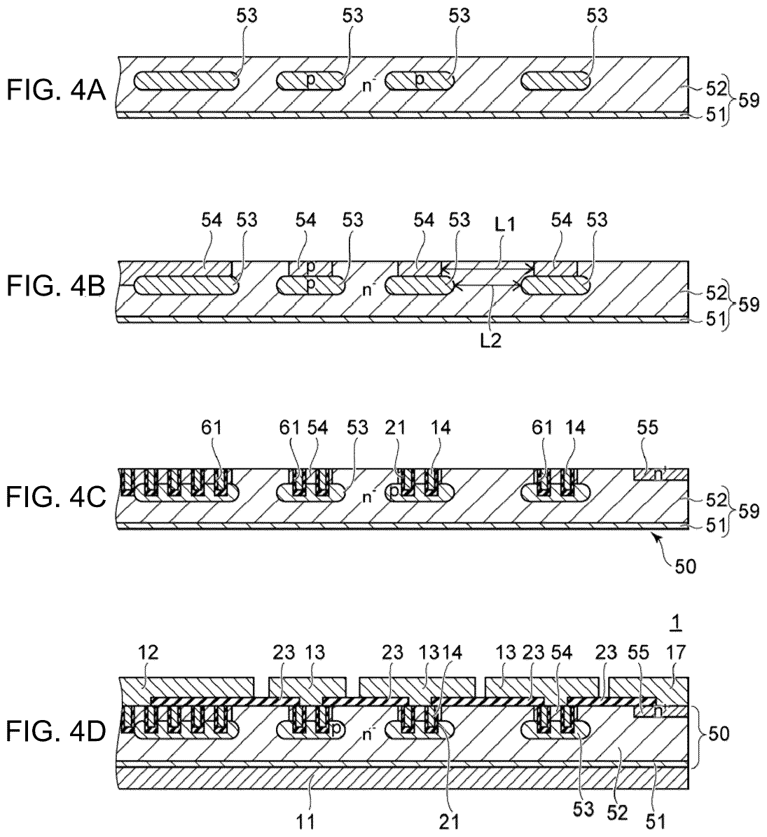

Next, the manufacturing method of the semiconductor device 1 according to this embodiment will be described. FIGS. 4A to 4D are process cross-sectional views showing the manufacturing method of the semiconductor device according to this embodiment. Note that FIGS. 4A to 4D show only the termination region Rt.

First, as shown in FIGS. 2A and 2B and FIG. 4A, a laminated body 59 in which an n+ type drain layer 51 is laminated on an n-type drift layer 52 is prepared. Then, an acceptor impurity is ion-implanted into the drift layer 52 at a high acceleration voltage. The dose amount at this time is, for example, 1×10\hat{ }12 cm\hat{ }−2 or more and less than 1×10\hat{ }13 cm\hat{ }−2. As a result, a guard ring layer 53 is formed in the termination region Rt of the drift layer 52. The guard ring layer 53 does not expose the upper surface of the drift layer 52.

Next, as shown in FIGS. 2A and 2B and FIG. 4B, an acceptor impurity is ion-implanted into the drift layer 52. The acceleration voltage of this ion implantation is lower than that of the ion implantation for forming the guard ring layer 53. In addition, the dose amount of this ion implantation is higher than that of the ion implantation for forming the guard ring layer 53, for example, higher than 1×10\hat{ }12 cm\hat{ }−2 and less than or equal to ×10\hat{ }13 cm\hat{ }−2.

As a result, in the termination region Rt, a p-type connection layer 54 is formed on the guard ring layer 53 within the drift layer 52. The connection layer 54 is in contact with the guard ring layer 53 and is exposed on the upper surface of the drift layer 52. In the cell region Rc, a p-type base layer 56 is formed on the drift layer 52. The carrier concentration of the connection layer 54 and the base layer 56 is higher than that of the guard ring layer 53. Note that in the process of forming the guard ring layer 53, the connection layer 54, and the base layer 56, no impurity diffusion process is performed.

Next, as shown in FIGS. 2A and 2B and FIG. 4C, for example, by lithography and RIE (Reactive Ion Etching), an FP trench 61 is formed in the termination region Rt, and a gate trench 62 is formed in the cell region Rc. The FP trench 61 penetrates the connection layer 54 and reaches the guard ring layer 53. The gate trench 62 penetrates the base layer 56 and reaches the drift layer 52.

Next, for example, by thermal oxidation, a trench insulating film 21 is formed on the inner surface of the FP trench 61, and a gate insulating film 22 is formed on the inner surface of the gate trench 62. Then, a conductive material is embedded in the FP trench 61 and the gate trench 62. For example, after depositing silicon containing impurities by CVD (Chemical Vapor Deposition), a planarization process such as CMP (Chemical Mechanical Polishing) is performed to remove the silicon deposited on the upper surface of the laminated body 59. As a result, a trench electrode 14 in contact with the trench insulating film 21 is formed in the FP trench 61, and a gate electrode 15 in contact with the gate insulating film 22 is formed in the gate trench 62.

Next, by ion-implanting a donor impurity, an n+ type termination layer 55 is formed in the termination region Rt, and an n+ type source layer 57 is formed on a part of the base layer 56 in the cell region Rc. In this way, the semiconductor portion 50 is formed.

Next, as shown in FIGS. 2A and 2B and FIG. 4D, a termination insulating film 23 is formed on the region of the termination region Rt of the semiconductor portion 50 where the drift layer 52 is exposed. Additionally, a cell insulating film 24 is formed on the region of the cell region Rc of the semiconductor portion 50 where the gate electrode 15 and the gate insulating film 22 are exposed.

Next, as shown in FIGS. 1, 2A and 2B, and FIG. 4D, a drain electrode 11 is formed on the entire lower surface of the semiconductor portion 50. Additionally, a source electrode 12 and a gate pad 16 are formed on the upper surface of the cell region Rc of the semiconductor portion 50, and an FP electrode 13 and a termination electrode 17 are formed on the upper surface of the termination region Rt. The drain electrode 11 is connected to the drain layer 51, the source electrode 12 is connected to the base layer 56 and the source layer 57, the gate pad 16 is connected to the gate electrode 15, the FP electrode 13 is connected to the connection layer 54, and the termination electrode 17 is connected to the termination layer 55. In this way, the semiconductor device 1 is manufactured.

The order of the above steps may be changed. For example, the FP trench 61 and the gate trench 62, the trench insulating film 21 and the gate insulating film 22, and the trench electrode 14 and the gate electrode 15 may be formed before forming the guard ring layer 53, after forming the guard ring layer 53 but before forming the connection layer 54 and the base layer 56, or after forming the termination layer 55 and the source layer 57.

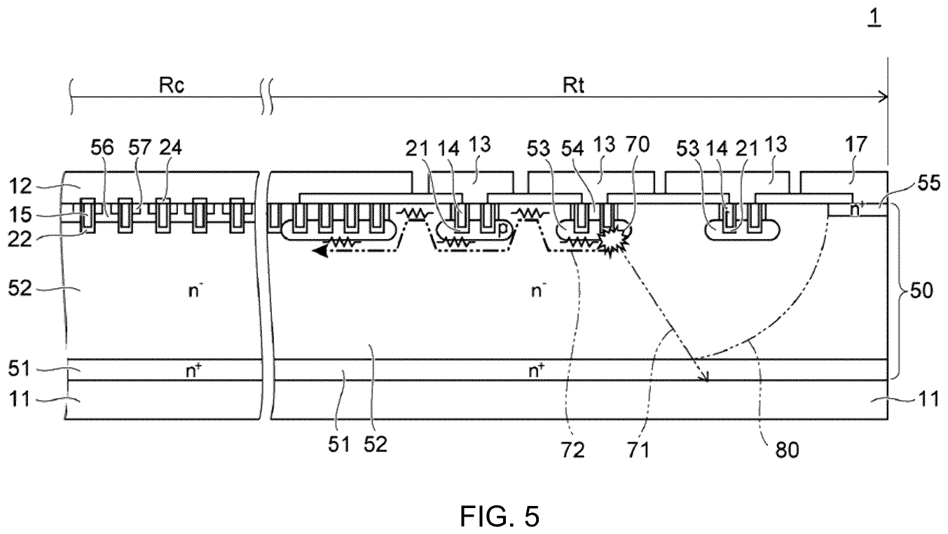

Next, the operation of the semiconductor device 1 according to this embodiment will be described. FIG. 5 is a cross-sectional view showing the operation of the semiconductor device according to this embodiment. As shown in FIGS. 2A and 2B, when a positive potential is applied to the drain electrode 11 and a negative potential is applied to the source electrode 12, a depletion layer spreads starting from the interface between the drift layer 52 and the base layer 56. In this state, when a potential above the threshold is applied to the gate electrode 15 via the gate pad 16, an inversion layer is formed in the portion of the base layer 56 in contact with the gate insulating film 22. As a result, current flows from the drain electrode 11 to the source electrode 12 in the cell region Rc, turning the semiconductor device 1 on. At this time, the thinner the semiconductor portion 50, the lower the on-resistance.

When a potential below the threshold is applied to the gate electrode 15 via the gate pad 16, the inversion layer disappears, and the semiconductor device 1 turns off. In the off state, a strong electric field is applied to the depletion layer, which may cause avalanche breakdown. The location where avalanche breakdown occurs can be controlled to some extent by the design of the semiconductor device 1, for example, it can be controlled to occur at the lower end of the trench insulating film 21.

As shown in FIG. 5, when avalanche breakdown occurs at the position 70 in contact with the lower end of the trench insulating film 21 in a certain guard ring layer 53, electron-hole pairs are generated at the position 70, and an electron current 71 flows from the position 70 toward the drain electrode 11. Since the outer edge 80 of the depletion layer curves toward the cell region Rc as it approaches the drain electrode 11, the electron current 71 tilts toward the termination of the semiconductor device 1 as it approaches the drain electrode 11.

On the other hand, a hole current 72 flows from the position 70 toward the source electrode 12. The hole current 72 tries to flow along the upper surface of the drift layer 52 taking the shortest distance to the source electrode 12, but is blocked by the trench insulating film 21 extending downward from the upper surface of the semiconductor portion 50, so it flows through the connection layer 54 and the guard ring layer 53, bypassing the trench insulating film 21. As a result, the path length of the hole current 72 becomes longer, and the resistance increases.

Next, the effects of this embodiment will be described. As described above, in this embodiment, when avalanche breakdown occurs, the trench insulating film 21 is interposed in the path of the hole current 72 to increase the resistance. By imparting a certain resistance to the hole current 72, it is possible to suppress the occurrence of negative resistance even if avalanche breakdown occurs. As a result, it is possible to suppress the concentration of current in the portion where avalanche breakdown occurs, and to prevent the semiconductor device 1 from being destroyed. Thus, according to this embodiment, it is possible to realize a semiconductor device that is less likely to be destroyed even if avalanche breakdown occurs.

In this embodiment, the carrier concentration of the guard ring layer 53 is set lower than that of the connection layer 54. As a result, the resistance of the hole current 72 increases more when passing through the guard ring layer 53.

Furthermore, in this embodiment, the distance D1 between the lower end of the trench insulating film 21 and the FP electrode 13 is set longer than the distance D2 between the center of the guard ring layer 53 and the FP electrode 13 in the vertical direction. The center of the guard ring layer 53 in the vertical direction is the part that is least likely to be depleted in the guard ring layer 53. Therefore, when the distance D1 is longer than the distance D2, the trench insulating film 21 penetrates the non-depleted part of the guard ring layer 53 and protrudes downward. As a result, the non-depleted part of the guard ring layer 53 is divided by the trench insulating film 21, increasing the resistance of the hole current 72.

Moreover, according to this embodiment, in the process shown in FIG. 4A, the guard ring layer 53 is formed inside the drift layer 52 by ion implantation of impurities at a high acceleration voltage. Then, in the process shown in FIG. 4B, the connection layer 54 is formed on the guard ring layer 53, and in the process shown in FIG. 4C, the FP electrode 13 is formed, connecting the guard ring layer 53 to the FP electrode 13. By forming the guard ring layer 53 and the connection layer 54 in two steps, it is not necessary to perform high-temperature, long-duration heat treatment to diffuse impurities. This reduces the manufacturing cost of the semiconductor device 1.

Additionally, according to this embodiment, the connection layer 54 is formed in the process of forming the base layer 56. Furthermore, the FP trench 61 is formed in the process of forming the gate trench 62, the trench insulating film 21 is formed in the process of forming the gate insulating film 22, and the trench electrode 14 is formed in the process of forming the gate electrode 15. Therefore, there is no need to provide a dedicated process for forming the connection layer 54, the FP trench 61, the trench insulating film 21, and the trench electrode 14. This also reduces the manufacturing cost of the semiconductor device 1.

### Second Embodiment

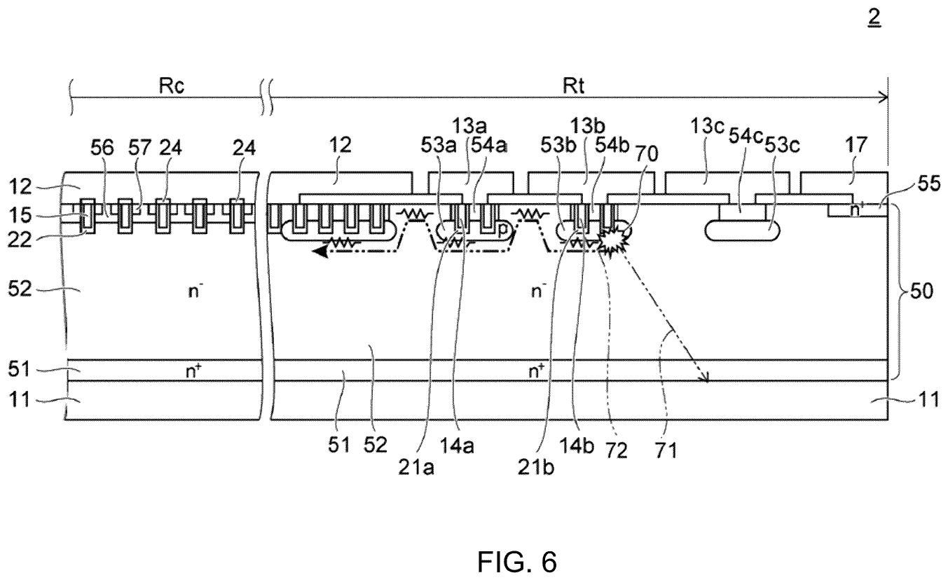

FIG. 6 is a cross-sectional view showing a semiconductor device according to this embodiment. As shown in FIG. 6, the semiconductor device 2 according to this embodiment differs from the semiconductor device 1 according to the first embodiment in that trench electrodes 14 and trench insulating films 21 are not disposed directly below some of the FP electrodes 13.

More specifically, two trench electrodes 14a and trench insulating films 21 are disposed directly below the FP electrode 13a located on the inner peripheral side of the semiconductor device 2, and two trench electrodes 14b and trench insulating films 21 are disposed directly below the FP electrode 13b located around the FP electrode 13a. However, no trench electrodes or trench insulating films are disposed directly below the FP electrode 13c located around the FP electrode 13b. However, the guard ring layer 53 and the connection layer 54 are disposed directly below the FP electrode 13c.

Since the hole current 72 does not flow to the terminal side beyond the position 70 where avalanche breakdown occurs, the resistance of the hole current 72 is not affected even if trench electrodes 14 and trench insulating films 21 are not disposed on the terminal side beyond the position 70. Therefore, if the position 70 where avalanche breakdown occurs can be accurately controlled, the trench electrodes 14 and trench insulating films 21 on the terminal side beyond that position can be omitted. The other configurations, manufacturing methods, operations, and effects in this embodiment are the same as those in the first embodiment.

### Third Embodiment

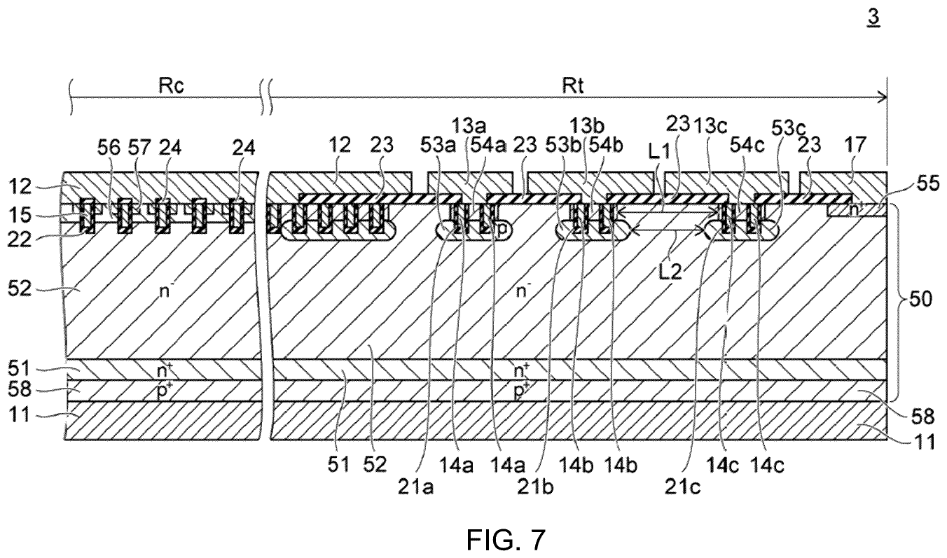

FIG. 7 is a cross-sectional view showing a semiconductor device according to this embodiment. As shown in FIG. 7, the semiconductor device 3 according to this embodiment is an IGBT. In the semiconductor device 3, instead of the drain layer 51 of the semiconductor device 1, a buffer layer 60 of n-type conductivity is provided. Additionally, a collector layer 58 is provided at the bottom of the semiconductor portion 50. The collector layer 58 has p+ type conductivity. The collector layer 58 is disposed between the drain electrode 11 and the buffer layer 60 and is in contact with both the drain electrode 11 and the buffer layer 60.

In the semiconductor device 3, the thinner the semiconductor portion 50, the fewer carriers enter the semiconductor portion 50 in the on-state, resulting in lower switching losses during turn-off. The other configurations, manufacturing methods, operations, and effects in this embodiment are the same as those in the first embodiment.

### Reference Example

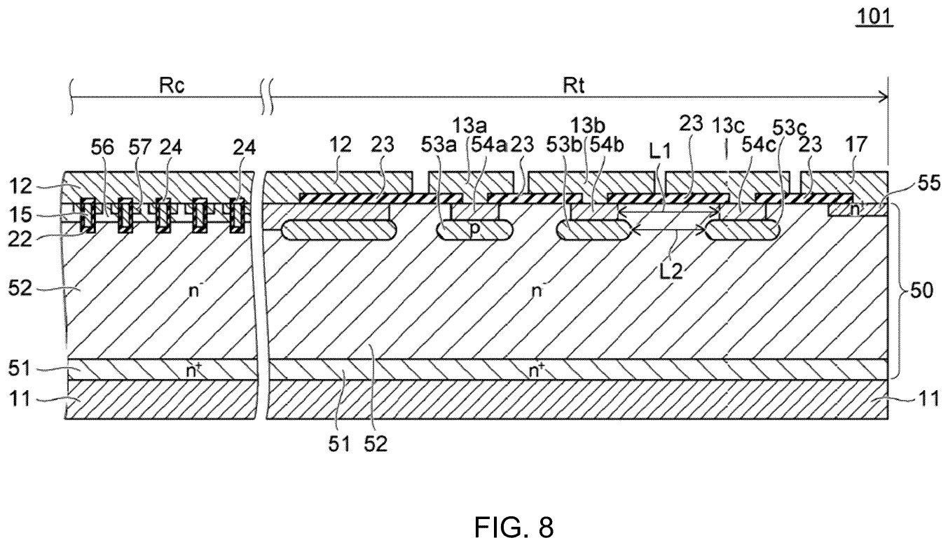

FIG. 8 is a cross-sectional view showing a semiconductor device according to this reference example. As shown in FIG. 8, the semiconductor device 101 according to this reference example differs from the semiconductor device 1 according to the first embodiment in that trench electrodes 14 and trench insulating films 21 are not disposed directly below any of the FP electrodes 13. However, the guard ring layer 53 and the connection layer 54 are disposed directly below each FP electrode 13. In the horizontal direction, the distance L1 between adjacent connection layers 54 is longer than the distance L2 between adjacent guard ring layers 53. The other configurations and manufacturing methods in this reference example are the same as those in the first embodiment.

### Comparative Example

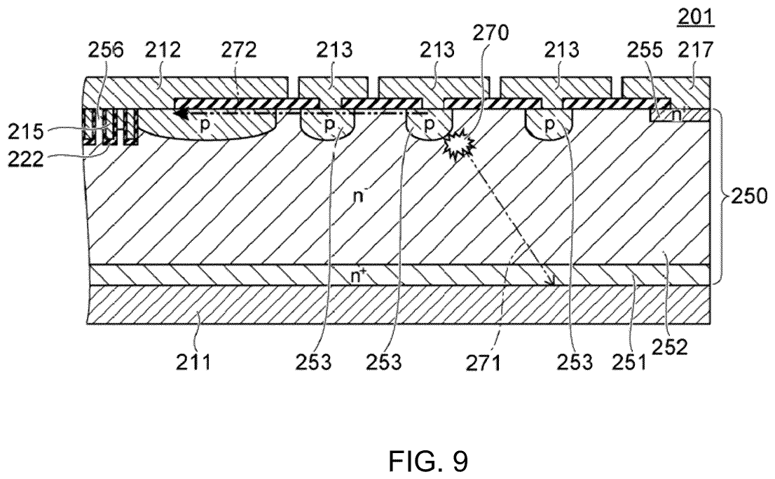

FIG. 9 is a cross-sectional view showing a semiconductor device according to this comparative example. As shown in FIG. 9, the semiconductor device 201 according to this comparative example differs from the semiconductor device 1 according to the first embodiment in that the guard ring layer 253 reaches the upper surface of the semiconductor portion 250 and is in contact with the FP electrode 213, and trench electrodes 14 and trench insulating films 21 are not disposed directly below the FP electrode 213.

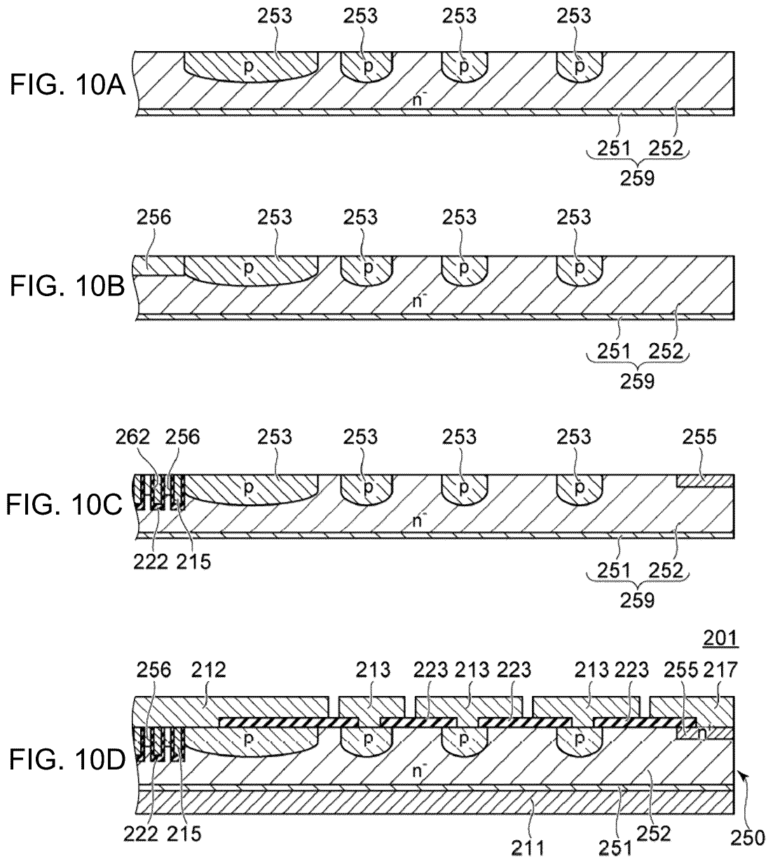

FIGS. 10A to 10D are process cross-sectional views showing the manufacturing method of the semiconductor device according to this comparative example. First, as shown in FIG. 9 and FIG. 10A, a laminated body 259 in which an n+ type drain layer 251 is laminated on an n-type drift layer 252 is prepared. Then, an acceptor impurity is ion-implanted. Then, heat treatment is performed at a temperature of 1100° C. or higher for 60 minutes or longer to diffuse the ion-implanted impurities to about 8 μm. As a result, the guard ring layer 253 is formed. The guard ring layer 253 reaches the upper surface of the semiconductor portion 250.

Next, as shown in FIG. 9 and FIG. 10B, an acceptor impurity is ion-implanted into the drift layer 252. As a result, a p-type base layer 256 is formed on the drift layer 252 in the cell region Rc. Note that the connection layer 54 is not formed at this time.

Next, as shown in FIG. 9 and FIG. 10C, a gate trench 262 is formed in the cell region Rc. The gate trench 262 penetrates the base layer 256 and reaches the drift layer 252. Note that the FP trench 61 is not formed in the termination region Rt at this time. Next, a gate insulating film 222 is formed on the inner surface of the gate trench 262. Then, a gate electrode 215 is formed in the gate trench 262.

Next, by ion-implanting a donor impurity, an n+ type termination layer 255 is formed in the termination region Rt, and an n+ type source layer (not shown) is formed on a part of the base layer 256 in the cell region Rc.

The subsequent steps are the same as those in the first embodiment. That is, as shown in FIG. 9 and FIG. 10D, a termination insulating film 223, a cell insulating film (not shown), a drain electrode 211, a source electrode 212, an FP electrode 213, a gate pad 216, and a termination electrode 217 are formed. In this way, the semiconductor device 201 is manufactured.

As shown in FIG. 9, in the semiconductor device 201 according to this comparative example, when avalanche breakdown occurs at position 270, an electron current 271 flows toward the drain electrode 211 and a hole current 272 flows toward the source electrode 212. The hole current 272 flows along the upper surface of the semiconductor portion 250 toward the source electrode 212 along the shortest path. Therefore, sufficient resistance cannot be imparted to the hole current 272, and negative resistance is likely to occur in the hole current 272.

When negative resistance occurs, current concentrates in its path, potentially destroying the semiconductor device 201. Additionally, in this comparative example, high-temperature, long-duration heat treatment is required to form the guard ring layer 253. This increases the manufacturing cost of the semiconductor device.

### Test Example

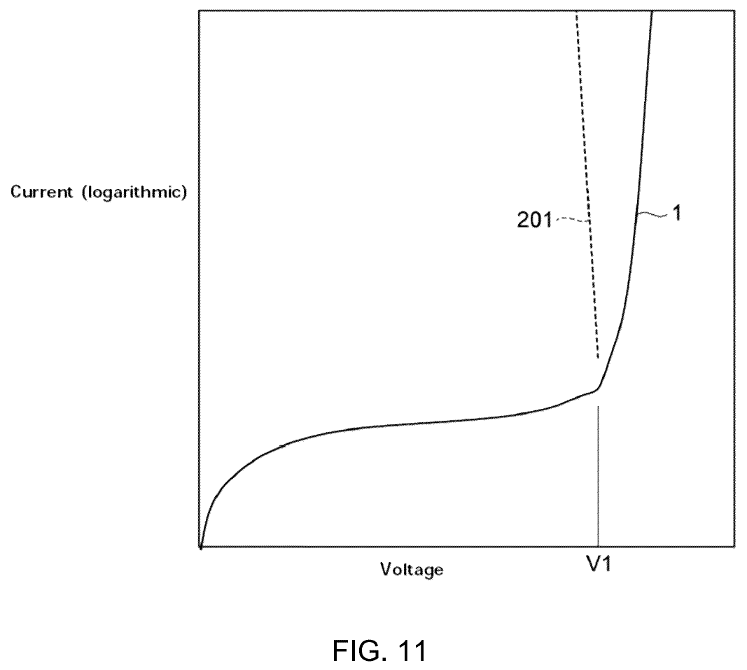

In this test example, simulations were conducted assuming the semiconductor device 1 according to the first embodiment and the semiconductor device 201 according to the comparative example, and the behavior when avalanche breakdown occurred was compared. FIG. 11 is a graph showing the I-V characteristics of the semiconductor device in this test example, with the voltage applied to the source electrode and drain electrode of the semiconductor device on the horizontal axis and the current flowing through the source electrode and drain electrode of the semiconductor device on the vertical axis.

As shown in FIG. 11, in the semiconductor device 201 according to the comparative example, after avalanche breakdown occurred at voltage V1, the slope of the graph became negative, indicating the occurrence of negative resistance. In contrast, in the semiconductor device 1 according to the first embodiment, even after avalanche breakdown occurred at voltage V1, the slope of the graph remained positive, suppressing the occurrence of negative resistance.

As described above, several embodiments of the present invention have been explained, but these embodiments are presented as examples and are not intended to limit the scope of the invention. These novel embodiments can be implemented in various other forms, and various omissions, substitutions, and changes can be made without departing from the gist of the invention. These embodiments and their modifications are included in the scope and gist of the invention, as well as in the scope of the invention described in the claims and their equivalents.

What is claimed is:

1. A semiconductor device comprising:
a first electrode;
a semiconductor portion disposed on the first electrode;
a second electrode disposed on a cell region of the semiconductor portion;
a third electrode disposed on a termination region of the semiconductor portion;
a fourth electrode disposed between the first electrode and the third electrode within the semiconductor portion, and connected to the third electrode;
a first insulating film disposed between the semiconductor portion and the fourth electrode.

2. The semiconductor device according to claim 1, wherein the fourth electrode is annular and surrounds the second electrode when viewed from above.

3. The semiconductor device according to claim 1, wherein the third electrode is annular and surrounds the second electrode when viewed from above.

4. The semiconductor portion comprising:
a first semiconductor layer of a first conductivity type connected to the first electrode;
a second semiconductor layer of a second conductivity type covering a lower part of the first insulating film;
a third semiconductor layer of the second conductivity type in contact with the second semiconductor layer and the third electrode.

5. The semiconductor device according to claim 4, wherein the carrier concentration of the third semiconductor layer is higher than that of the second semiconductor layer.

6. The semiconductor device according to claim 4, wherein the distance between the lower end of the first insulating film and the upper end of the semiconductor portion in the vertical direction is longer than the distance between the center of the second semiconductor layer and the upper end of the semiconductor portion.

7. The semiconductor device according to claim 4, further comprising:
a fifth electrode disposed between the first electrode and the second electrode within the semiconductor portion;
a second insulating film disposed between the semiconductor portion and the fifth electrode; wherein the semiconductor portion further comprises:
a fourth semiconductor layer of the second conductivity type disposed on the first semiconductor layer and in contact with the second insulating film;
a fifth semiconductor layer of the first conductivity type disposed on the fourth semiconductor layer and connected to the second electrode; wherein the carrier concentration of the fourth semiconductor layer is higher than that of the second semiconductor layer.

8. The semiconductor device according to claim 4, wherein the semiconductor portion further comprises a sixth semiconductor layer of the second conductivity type disposed between the first electrode and the first semiconductor layer.

9. The semiconductor device according to claim 4, wherein the third electrode, the second semiconductor layer, and the third semiconductor layer are provided in plurality, and the plurality of second semiconductor layers and the plurality of third semiconductor layers are each annular when viewed from above.

10. The semiconductor device according to claim 9, wherein the fourth electrode and the first insulating film are not disposed at a position in contact with the outermost second semiconductor layer among the plurality of second semiconductor layers.

11. A method for manufacturing a semiconductor device, comprising:
forming a second semiconductor layer of a second conductivity type in a termination region of a first semiconductor layer of a first conductivity type by ion implantation of impurities into the first semiconductor layer;
forming a third semiconductor layer of the second conductivity type, which is exposed on the upper surface of the first semiconductor layer and has a higher carrier concentration than the second semiconductor layer, on the second semiconductor layer within the first semiconductor layer by ion implantation of impurities into the first semiconductor layer;
forming a first trench penetrating the third semiconductor layer and reaching the second semiconductor layer;
forming a first insulating film on the inner surface of the first trench;
forming a fourth electrode in contact with the first insulating film within the first trench;
forming a first electrode connected to the first semiconductor layer, a second electrode disposed on a cell region of the first semiconductor layer, and a third electrode connected to the fourth electrode.

12. The method for manufacturing a semiconductor device according to claim 11, further comprising:
forming a fourth semiconductor layer of the second conductivity type on the cell region of the first semiconductor layer in the step of forming the third semiconductor layer;
forming a second trench penetrating the fourth semiconductor layer and reaching the first semiconductor layer in the step of forming the first trench;
forming a second insulating film in the second trench in the step of forming the first insulating film;
forming a fifth electrode in contact with the second insulating film within the second trench in the step of forming the fourth electrode;
forming a fifth semiconductor layer of the first conductivity type on a part of the fourth semiconductor layer;
wherein the second electrode is connected to the fifth semiconductor layer.
